(19) United States
(12) Patent Application Publication
(10) Pub. No.: US 2013/0181758 A1
(43) Pub. Date: Jul. 18, 2013

(54) Device and Method For Generating Noise Signals and Use Of a Device For Generating Noise Signals

(71) Applicant: tecData AG, Uzwil (CH)

(72) Inventors: Urs BÜHLER, Uzwil (CH); Ralf OTTE, Weinheim (DE); Frank BERGMANN, Grunheide (DE)

(73) Assignee: tecData AG, Uzwil (CH)

(21) Appl. No.: 13/711,905

(22) Filed: Dec. 12, 2012

(30) Foreign Application Priority Data
Dec. 13, 2011 (EP) 11193189.5

(51) Int. Cl. H03B 29/00; G01R 31/26

(52) U.S. Cl. CPC H03B 29/00; G01R 31/2607
USPC 327/164; 324/762.01

(57) ABSTRACT

The present invention firstly relates to a device for generating noise signals. Said device comprises at least one avalanche diode which is arranged in such a way that it is reverse-biased during intended operation of the device. Moreover, the invention relates a method for generating a noise signal by means of such a device and to a use of said device and to a method for evaluating a type of an avalanche diode or of an avalanche transistor.

The invention relates to a device for generating noise signals which can be used, in particular, in systems for the analogue and digital generation of noise and random signals. Furthermore, the invention relates to a method and a use for operating such a device, and to a method for evaluating a type of an avalanche diode or of an avalanche transistor.

### BACKGROUND OF THE INVENTION

In physics, noise is generally understood to be a disturbance variable having a wide non-specific frequency spectrum. It can therefore be interpreted as a superimposition of a plurality of oscillations or waves having different amplitudes and frequencies or wavelengths.

Noise was described for the first time in 1918 by Walter Schottky as a physical phenomenon, namely as measurable current fluctuations. If these fluctuations are amplified and made audible, then a sound is obtained: the noise. Nowadays the definition is a little more general: noise is a temporally variable power-limited signal whose properties can be described mathematically by a random process. Types of noise are often classified according to their power density. The latter corresponds to the change in power per bandwidth. When simplified, this means a dependence on frequency.

A distinction is made between two basic types of noise:

White noise (e.g. shot noise, thermal noise) in the engineering and natural sciences is a noise that encompasses all frequencies with a constant amplitude. In practice, this signal cannot be generated since any technical processing has only a limited frequency coverage. Therefore, only the following type of noise is of technical importance:

Pink noise (e.g. 1/f noise) has a power spectral density that decreases with frequency. In the case of pink noise, the low frequencies (low tones) have a higher amplitude than higher frequencies (high tones). The amplitude decreases inversely proportionally with increasing frequencies, but all frequencies are represented. 1/f noise is a noise that occurs in many physical, biological but also economic processes. An exemplary spectrum representing an approximate 1/f noise is reproduced in FIG. 1. This noise behaviour can be observed whenever specific events occur only half as intensively at double the speed (or at double the frequency). This can easily be comprehended because the expenditure for changes naturally increases further and further with their speed.

Commercial applications for noise signal generation use primarily the following noise sources:

resistors,

Zener diodes,

transistors.

These noise sources have typical amplitude values of 10 μV to 10 mV. Since the disturbance signals in electronic systems are often within these dimensions, technically complex measures are necessary to guarantee a sufficiently high signal-to-noise ratio. Such disturbance signals may be, for example: a mains frequency; common-mode signals originating from a crystal generator, multivibrators, processor or system clocks; and artefacts from the technical environment of the application. Therefore, new noise sources having primarily

high noise signal amplitudes,

a wide frequency spectrum and

a high reproducibility

are being sought worldwide.

Analogue noise signals are required primarily where the detailed quantized curve profile permits conclusions to be drawn about information contained. In this case, it is absolutely necessary to achieve a signal-to-noise ratio that is as high as possible. This is because any amplification of a noise signal likewise amplifies the disturbance voltages modulated primarily on the supply voltage. Thus, the random signal generator from Protego (www.protego.se) has a noise source having a primary signal amplitude of approximately 10 μV and is amplified approximately 15,000-fold.

Many areas in information technology are increasingly relying on random numbers. Such random numbers can be generated from a noise signal in a manner known per se by said noise signal being digitally sampled, for example with the aid of a Schmitt trigger. As a result of the increasing worldwide networking of computers, security aspects have gained in importance in recent years. Digitized noise signals are therefore often used for statistical examinations and for generating cryptographic parameters. A high entropy is primarily required in these applications. Here, too, artefacts, disturbance signals and a low signal-to-noise ratio bring about a reduction of the entropy and are often a much sought approach in cryto-analysis.

FIG. 2 shows a noise signal transformed by means of a fast Fourier transformation. For this purpose, firstly a primary noise signal was generated with the aid of a reverse-biased transistor, which was operated at a reverse voltage of 5 V. The output signal of the transistor had only a very low primary noise signal amplitude, and so a large amplification was necessary in order to obtain amplitudes of the technically usable order of magnitude of at least approximately 100 mV. FIG. 2 shows the Fourier transformation of this already amplified noise signal. However, the amplification also amplified disturbance signals detrimental to the quality of the noise signal. Thus, significant disturbance signals can be discerned at the frequencies 12.5 MHz and 25 MHz, for instance, which corrupt statistical assessments and signal analyses.

The quality of the noise can be determined using mathematical-statistical methods known per se, such as, for example, the AIS31 method or the NIST test and the diehard test. The Shannon entropy (hereinafter “entropy”) of an 8-bit noise signal is determined with the aid of the AIS31 method. This entropy has a theoretical maximum value of 8 for such an 8-bit signal; it has a theoretical maximum value of n for a general n-bit signal. In general and in particular in cryptography, a noise signal is ascribed a good quality if the value of the entropy of an n-bit noise signal is greater than n/8×7.97—that is to say greater than 7.97 in the case of an 8-bit noise signal.

Requirements made of an ideal white noise source include, inter alia:

highest possible signal-to-noise ratio (i.e. a high noise signal amplitude and a small disturbance signal);

as few artefacts as possible or even no artefacts at all (such as, for example, those shown in FIG. 2);

highest possible bandwidth (ideally the frequency response of white noise);

highest possible average frequency (for example, all the more random numbers can be generated per unit time given, the higher the frequency).

### SUMMARY OF THE INVENTION

Therefore, it is an object of the invention to provide a device for generating noise signals which meets these requirements to the highest possible extent. In particular, the intention is to generate a primary noise signal which, when it is generated, already has such a high noise signal amplitude that only a relatively small or even no amplification whatsoever of the primary noise signal is necessary. Here and hereinafter, the “primary noise signal” is always understood to mean the unamplified noise signal. In addition, in particular the noise signal is intended to have the highest possible quality. In particular, an n-bit noise signal is intended to have an entropy of more than n/8×7.97 (that is to say more than 7.97 in the case of an 8-bit noise signal) in order that it meets the requirements of cryptography.

In accordance with a first aspect of the invention, this is achieved by means of a device comprising at least one avalanche diode which is arranged in such a way that it is reverse-biased during intended operation of the device.

The intended operation of the device is evident to the person skilled in the art from the construction of said device. In particular, the person skilled in the art can recognize from the construction of the device the polarity with which the device is connected or is to be connected to a voltage source. From this connection to the voltage source, the avalanche diode polarity that is essential according to the invention is also evident.

The voltage source can itself be part of the device. However, the device can also contain terminals which can be connected to a separate voltage source.

Preferably, the avalanche diode is formed by a part of an avalanche transistor. In principle, a transistor consists of two series-connected diodes, wherein one diode is formed by the emitter-base junction of the transistor and the other diode is formed by the base-collector junction of the transistor. Preferably, the avalanche diode is formed by the emitter-base junction of the avalanche transistor.

The transistor can be a pnp transistor or an npn transistor.

The transistor can be a small-signal transistor, for example. In the context of the present invention, a transistor is designated as a small-signal transistor if it has a power loss of less than 1 watt. Such small-signal transistors are distinguished by their small structural size and not least also by their low price.

The invention therefore uses semiconductor components that utilize, in particular, avalanche breakdown, also referred to as the avalanche effect. This is characterized by a steep rise in the current at a specific reverse voltage of a semiconductor p-n junction if the semiconductor component is reverse-biased. Avalanche breakdown is triggered by the avalanche effect (also called avalanche multiplication or carrier multiplication). In general, the Zener effect and avalanche effect act simultaneously in practice. Diodes and transistors can be protected against destruction by overvoltages by means of a controlled avalanche behaviour.

As has been found in experiments, the—according to the invention—high primary noise signal amplitude is dependent on the extent of the avalanche effect in the diode, in particular in the emitter-base junction of the avalanche transistor. Data sheets for semiconductor components at least in general do not contain information about the avalanche effect. As has surprisingly been ascertained, individual types of diodes and, in particular, of transistors yield particularly high primary noise signal amplitudes. Suitable types of diodes and transistors for noise generation can, in particular, also be determined empirically by a method as described below. Transistors are regarded as suitable also when primary noise voltages of at least 100 mV and/or average noise frequencies of at least 1 MHz can be generated thereby. The inventors have discovered that Zener effect and noise spectrum or noise signal amplitude correlate with one another. Moreover, it has been found that transistors within a specific type (for example the BC856C type) practically do not differ in their suitability. Therefore, if one transistor is suitable in the above sense, then this applies substantially to all other transistors of the same type. Different transistors of one and the same type can have different Zener voltages. However, all examined and suitable semiconductor components having a large primary noise signal amplitude had a Zener voltage in the range of 7.0 V to 12.0 V, in particular of 9.5 V to 11.0 V.

### BRIEF DESCRIPTION OF THE DRAWINGS

In the accompanying drawings,

FIG. 1 is an exemplary spectrum representing an approximate 1/f noise;

FIG. 2 is a noise signal transformed by means of a fast Fourier transformation;

FIGS. 3a to 3g illustrate noise signals achieved with the aid of seven avalanche transistors;

FIGS. 4a and 4b are circuit diagrams for two devices for generating noise signals;

FIGS. 4c and 4d show signals generated by the circuits according to FIGS. 4a and 4b, respectively;

FIG. 5 is a diagram of a circuit comprising a total of 14 parallel-connected avalanche transistors;

FIGS. 6a to 6d show noise signals generated by the circuit according to FIG. 5 at four different operating points;

FIGS. 7a to 7c show noise signals recorded with a circuit in accordance with FIG. 4a at different temporal resolutions of the noise signal;

FIG. 8 shows a signal of a circuit comprising seven series-connected transistors;

FIG. 9 is a diagram of an apparatus comprising a device for generating noise and a standard microcontroller; and

FIG. 10 shows the entropy of a digitized 8-bit noise signal.

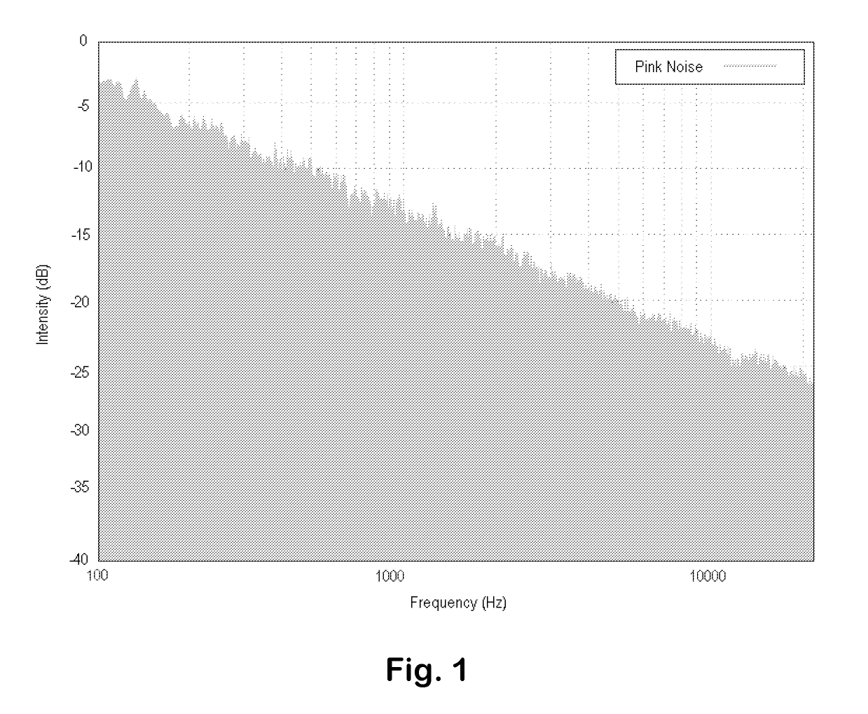

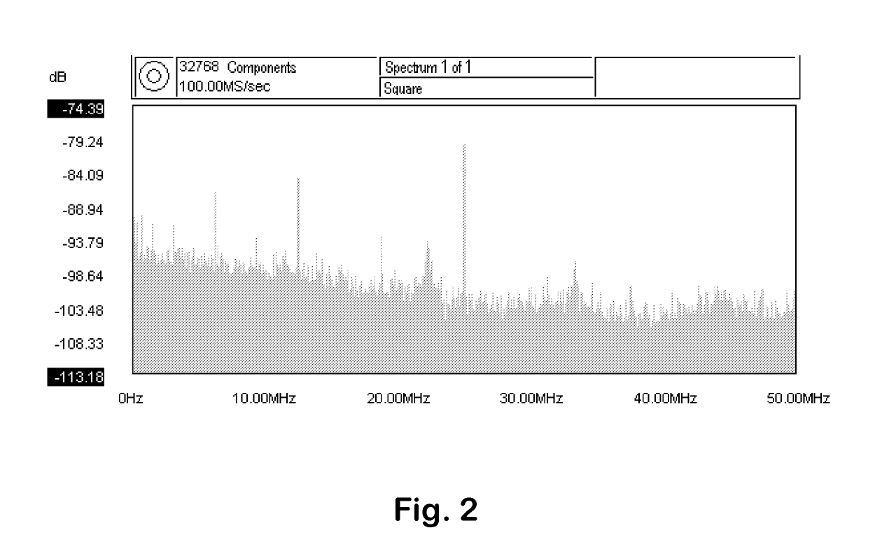

### DESCRIPTION OF THE PREFERRED EMBODIMENT

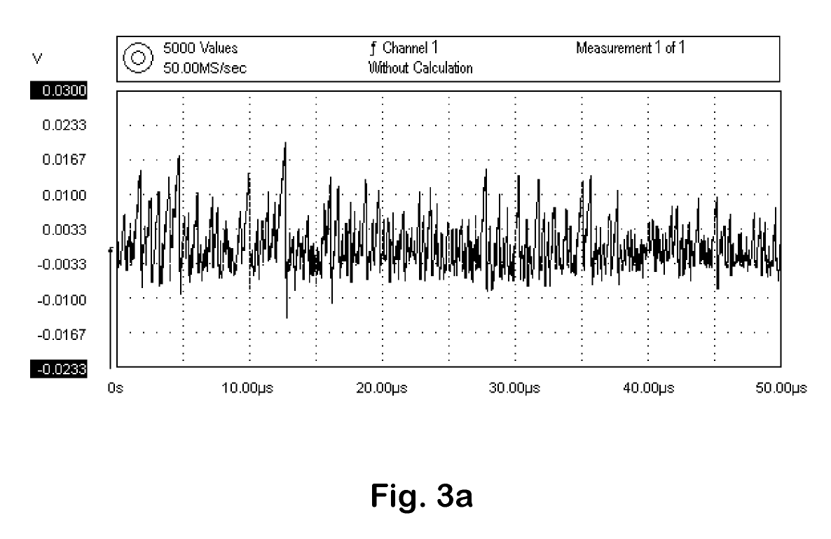

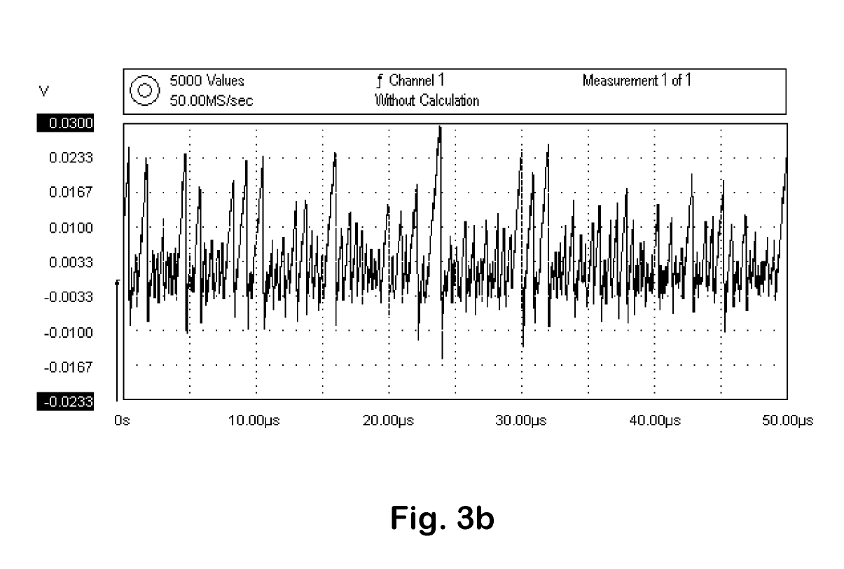

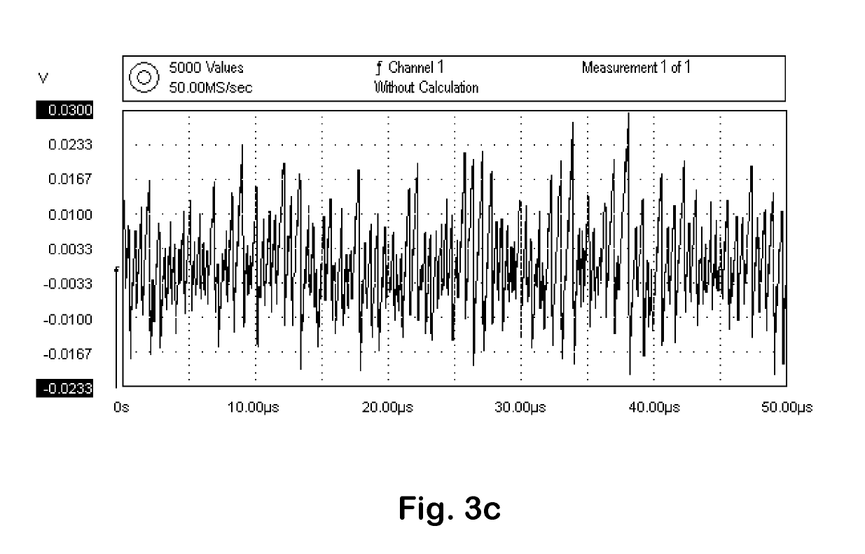

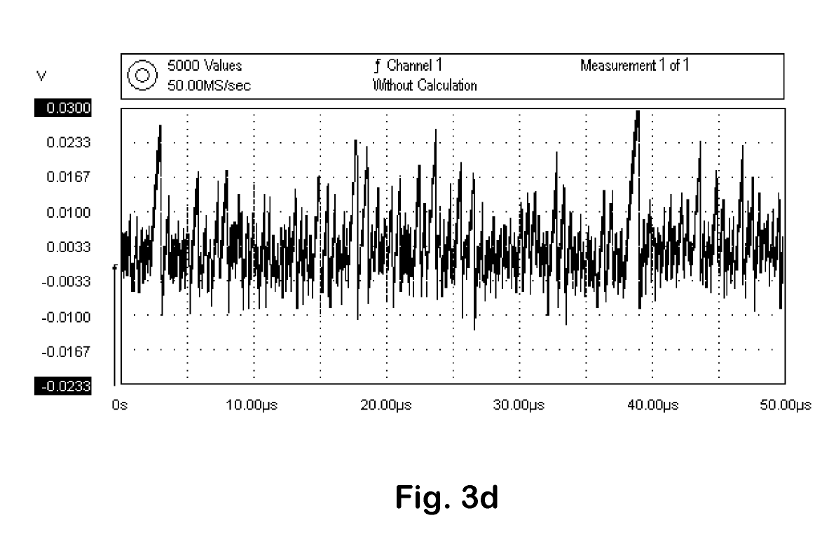

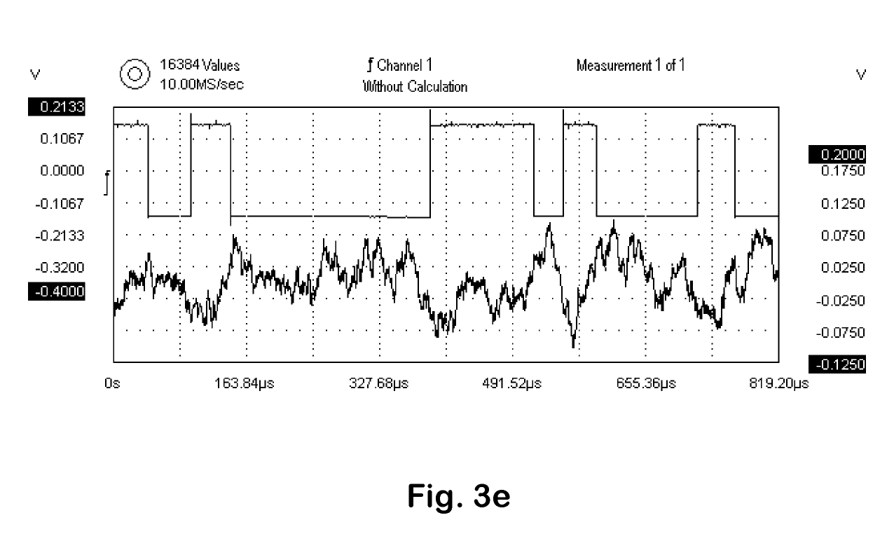

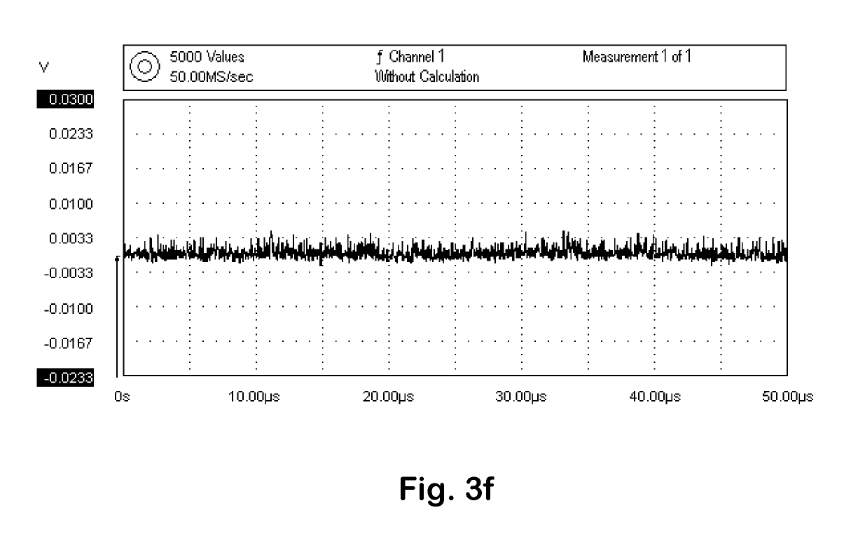

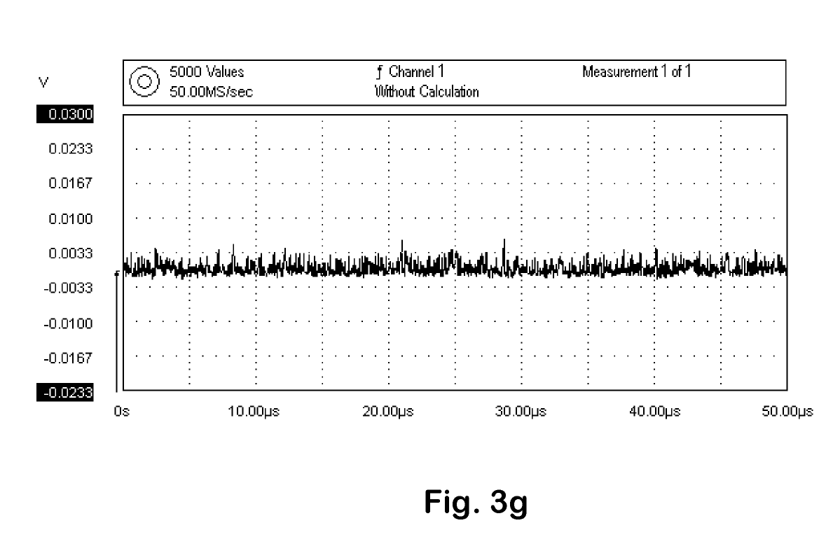

FIGS. 3a to 3g illustrate noise signals that were achieved with the aid of the following seven avalanche transistors:

| | Type of | Polarity of the | Zener voltage |
|---|---|---|---|
| Figure | Transistor | Transistor | [V] |
| 3a | BCW70 | pnp | 10.56 |
| 3b | BCW70 | pnp | 10.68 |
| 3c | BCW70 | pnp | 10.14 |
| 3d | BCW70 | pnp | 10.62 |
| 3e | BC817 | npn | 9.26 |
| 3f | BC856C | npn | 9.43 |
| 3g | BC847A | npn | 7.62 |

All type designations are in each case in accordance with the European Semiconductor Industry Association (EECA).

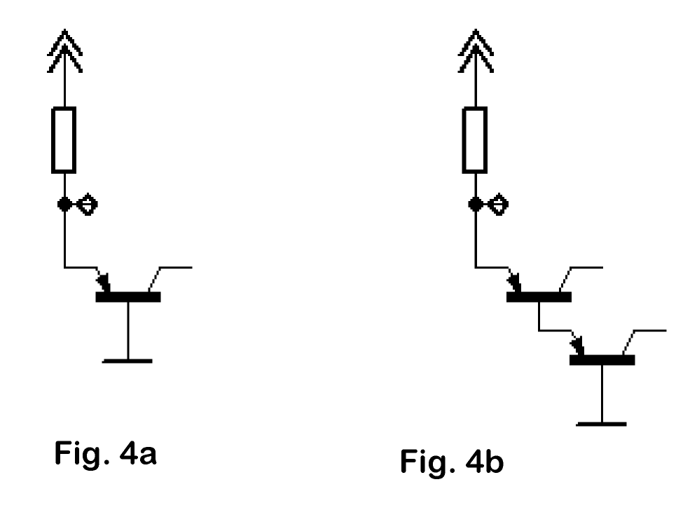

These seven transistors were used in the circuit illustrated in FIG. 4a (see below). The noise signals in accordance with FIGS. 3a-3g were obtained from the primary, i.e. unamplified, noise signals generated by this circuit. The noise signal amplitudes are a few 10 mV in the examples shown in FIGS. 3a-3d, and even above 100 mV in FIG. 3e. However, the noise signal amplitudes are significantly smaller in the case of the examples in accordance with FIGS. 3f and 3g. For this reason, the first five transistors are particularly suitable for the present invention.

It becomes clear from the examples in accordance with FIGS. 3a-3d that different transistors of one and the same type (here BCW70) can have different Zener voltages. In FIG. 3e, the lower curve shows a noise signal and the upper curve shows the digitization thereof, which was effected by means of a Schmitt trigger.

According to statistical surveys, approximately 25% of all small-signal transistors yield particularly high primary noise signal amplitudes, in particular if both the Zener effect and the avalanche effect are present.

Further suitable types of avalanche transistors and associated Zener voltages are reproduced in the following table:

| Type of | Polarity of |
|---|---|
| the transistor | the transistor |
| 2DD2652 | Npn |
| (Zener voltage | |
| e.g. 8.02 V) | |
| BC850B | Npn |
| BCW70 | Pnp |
| BC807 | Pnp |
| BC846B | Npn |
| MMBTA42 | Npn |
| BC860C | Pnp |
| BCW30 | Pnp |
| BC857A | Pnp |

Preferably, the device contains at least two diodes, more preferably at least five diodes. In particular, it can contain at least two transistors, more preferably at least five transistors. A plurality of diodes, in particular a plurality of transistors, were actually expected to mutually disturb one another thus entirely precluding a controlled avalanche breakdown. It was totally surprising to discover, however, that the effect of the individual diodes, in particular transistors, can thereby be cumulated, as a result of which the quality and, in particular, the noise signal amplitude of the noise can be increased.

It has furthermore been found that in general a maximum of 14 transistors suffice to generate a primary noise signal having the required noise signal amplitude.

It is particularly advantageous if the device comprises at least two series-connected diodes which are arranged in such a way that they are reverse-biased during intended operation of the device. In the case of such a series connection, it is conceivable in at least in some exemplary embodiments that, instead of an avalanche diode, other diodes are also used, such as Zener diodes, for example.

In these preferred exemplary embodiments, too, the diodes can in each case be formed by a part of the transistor, preferably by the emitter-base junction of a transistor. In the series connection, preferably the base of a first pnp transistor is connected to the emitter of a second pnp transistor.

FIGS. 4a and 4b show circuit diagrams for two devices for generating noise signals. The circuit in accordance with FIG. 4a contains a single pnp transistor, while the circuit illustrated in FIG. 4b contains two pnp transistors. Said transistors are avalanche transistors in each case. In FIG. 4b, here the base of one pnp transistor is connected to the emitter of the second pnp transistor. In both cases, the collectors of the transistors remain unconnected; therefore, only the base-emitter junction is used in each case. The transistors can be for example of the BCW70 type having a Zener voltage 10.91 V. The resistors, which can have a value of 100 kΩ, serve for setting the operating current that flows through the transistor or transistors.

FIGS. 4c and 4d illustrate the signals generated by the circuits, which signals were recorded by an oscilloscope. In this case, FIG. 4c shows the signal of the circuit in accordance with FIG. 4a comprising one transistor; the primary, unamplified noise signal amplitude here is 428 mV and the average frequency is 1.38 MHz. FIG. 4d reproduces the signal of the circuit in accordance with FIG. 4b comprising two transistors; here the primary, unamplified noise signal amplitude is even 864 mV, that is to say is more than twice as large as with a single transistor and even almost two orders of magnitude larger than in the case of the transistors used hitherto. The average frequency is 2.16 MHz in the example in accordance with FIG. 4d.

As an alternative or in addition to the series connection, it is also possible for at least two transistors to be connected in parallel with one another. With the use of two or three transistors connected in parallel with one another, the noise frequency increases. Preferably, however, not more than three transistors should be connected in parallel with one another, since otherwise there is the risk of the noise sources mutually cancelling one another by superimposition.

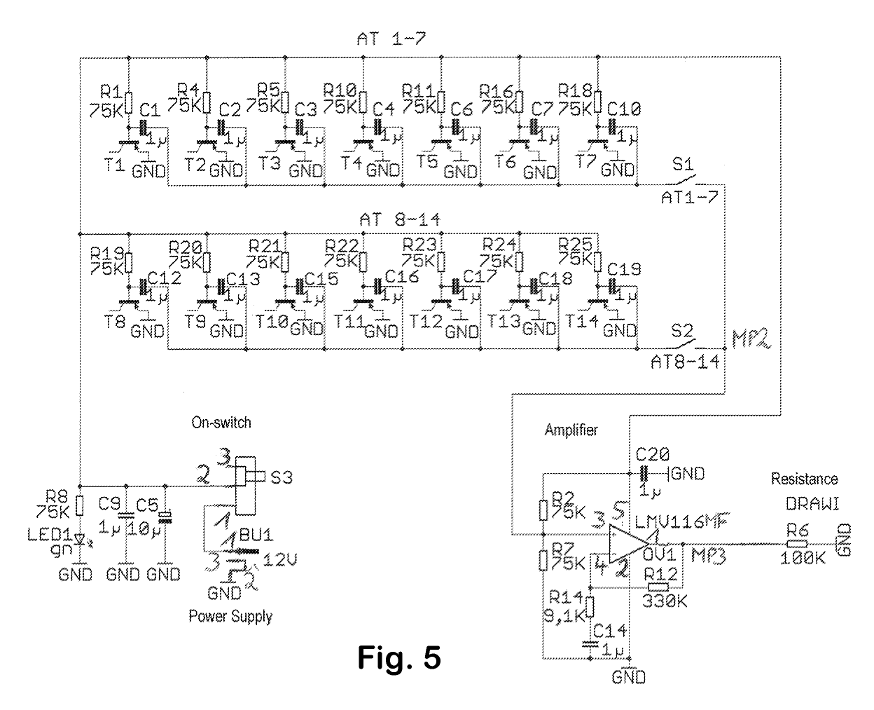

FIG. 5 shows a circuit comprising a total of 14 parallel-connected avalanche transistors T1 to T14 of the BCW70 type. The emitters of the transistors T1 to T14 are in each case connected to ground. The collectors of the transistors T1 to T14 remain unconnected; therefore, only the base-emitter junction of the transistors T1-T14 is used in each case. The transistors T1 to T7 are connected to a first measurement point MP2 via a respective capacitor C1-C4, C6, C7 and a common first switch S1. The transistors T8 to T14 are connected to the first measurement point MP2 via a respective capacitor C10, C12, C13 and C15-C19 and a common second switch S2. With the aid of the capacitors C1-C4, C6, C7, C10, C12, C13 and C15-C19 (1 μF in each case), the generated noise signal is decoupled from DC voltage components. The unamplified noise signal can be tapped off at the measurement point MP2 relative to ground.

By means of an operational amplifier OV1, the noise signal present at the first measurement point MP2 can be amplified and then tapped off at a second measurement point MP3 relative to ground. This amplified noise signal is present at the resistor R6.

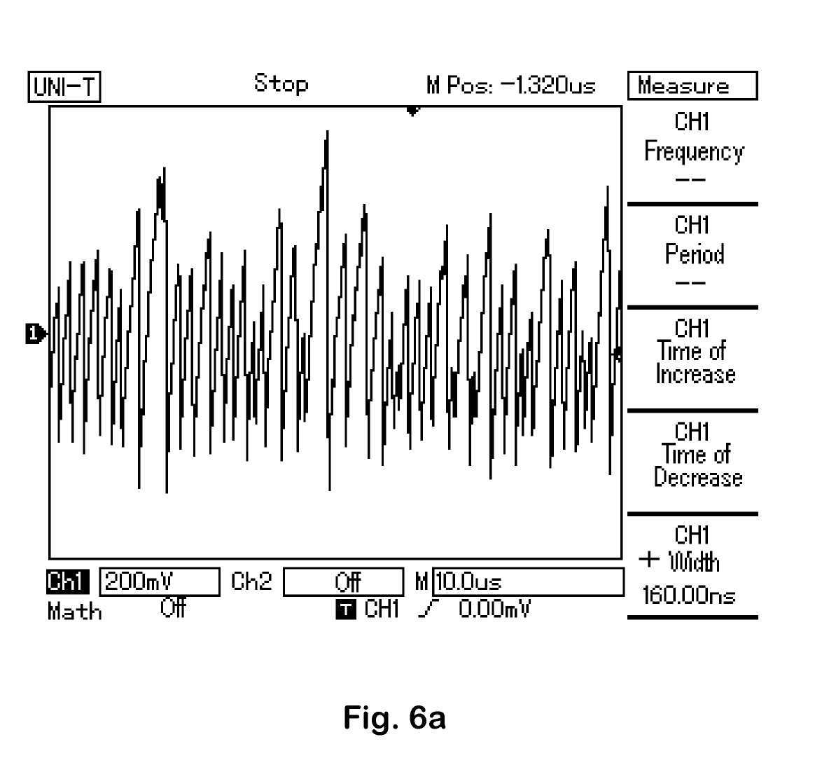

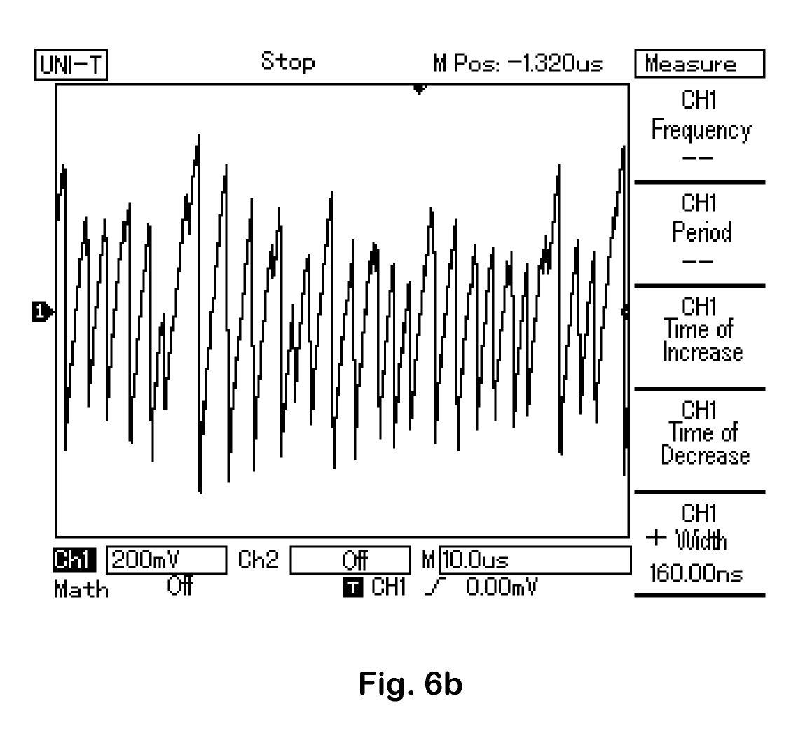

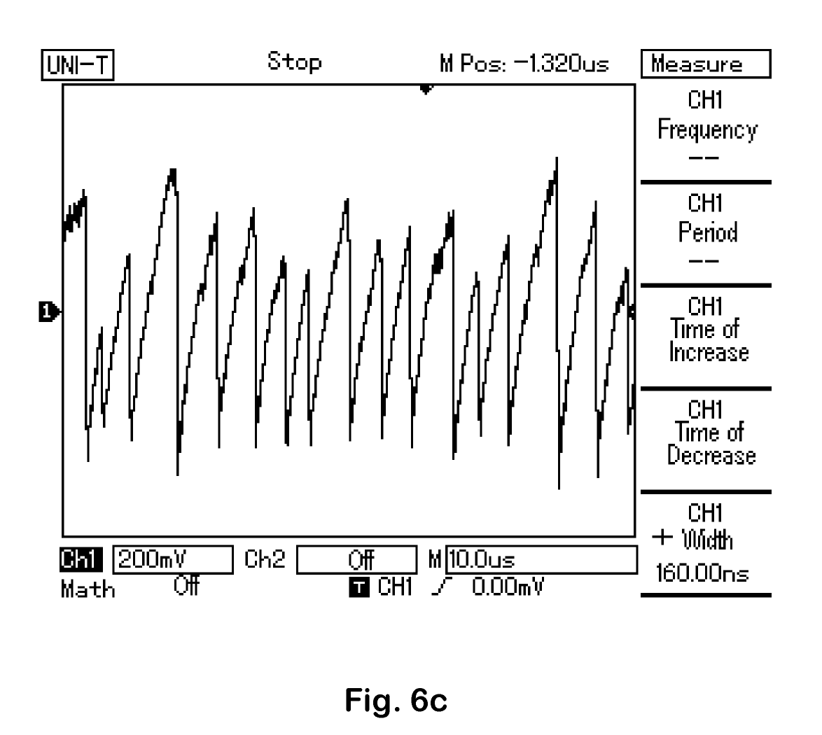

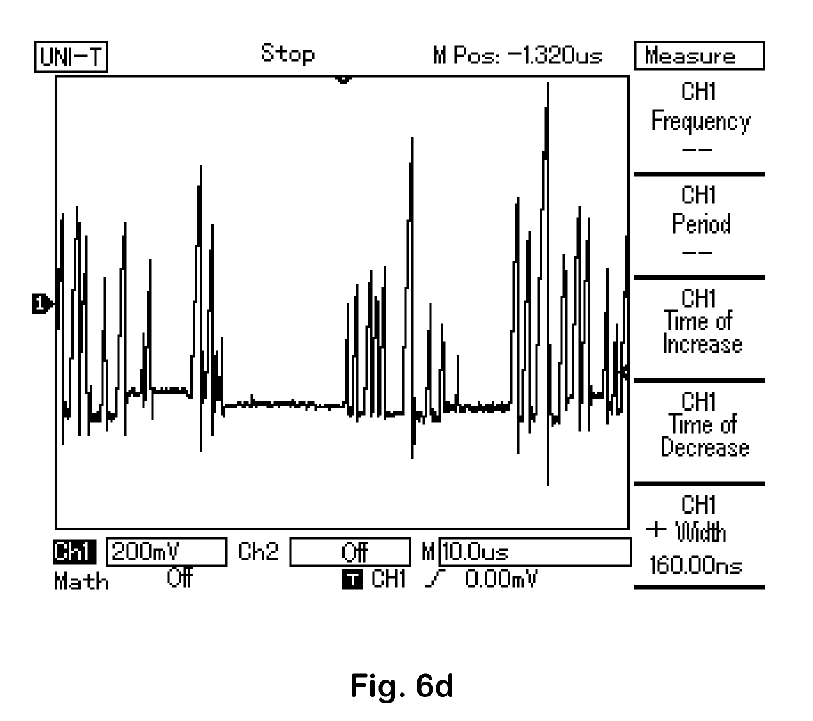

The operating point of the transistors T1-T14 can be set by means of current limiting with a respective resistor R1, R4, R5, R10, R11, R16 and R18-R25 (75 kΩ in each case) to 20 to 60 μA. Here and hereinafter, the operating point is understood to mean the current flowing through the emitter-base junction of the transistor. The choice of the operating point determines the noise spectrum. This can be discerned in FIGS. 6a to 6d, which illustrate the noise signal for different operating points. The respective operating points can be gathered from the following table:

| | Operating point |
|---|---|
| Figure | [μA] |
| 6a | 20 |
| 6b | 35 |
| 6c | 50 |
| 6d | 90 |

By increasing the operating point, the average noise frequency increases. At an operating point of 90 μA or more, a continuous noise spectrum is no longer possible: undefined artefacts arise, as made clear by FIG. 6d.

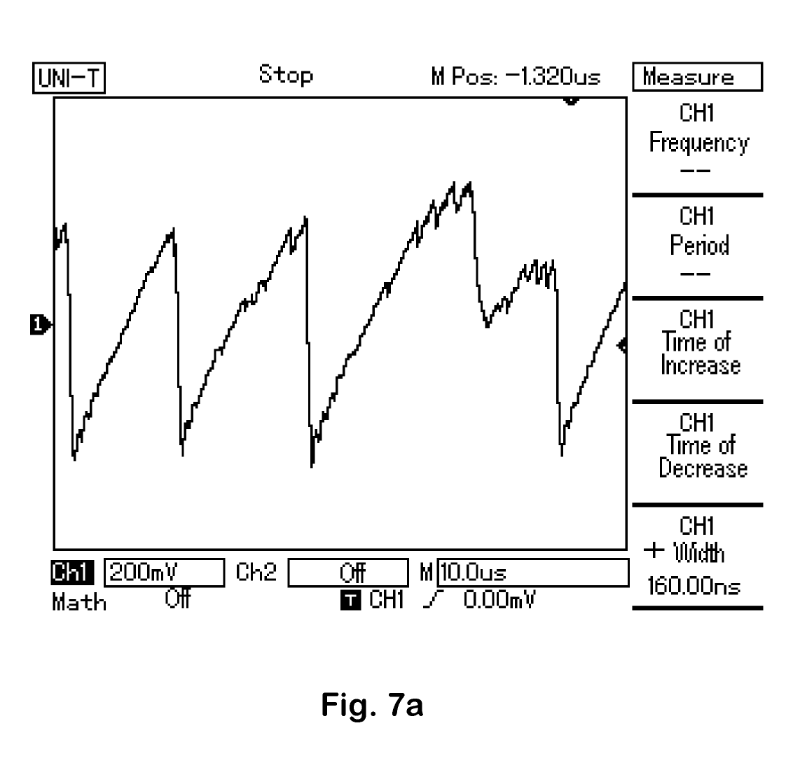

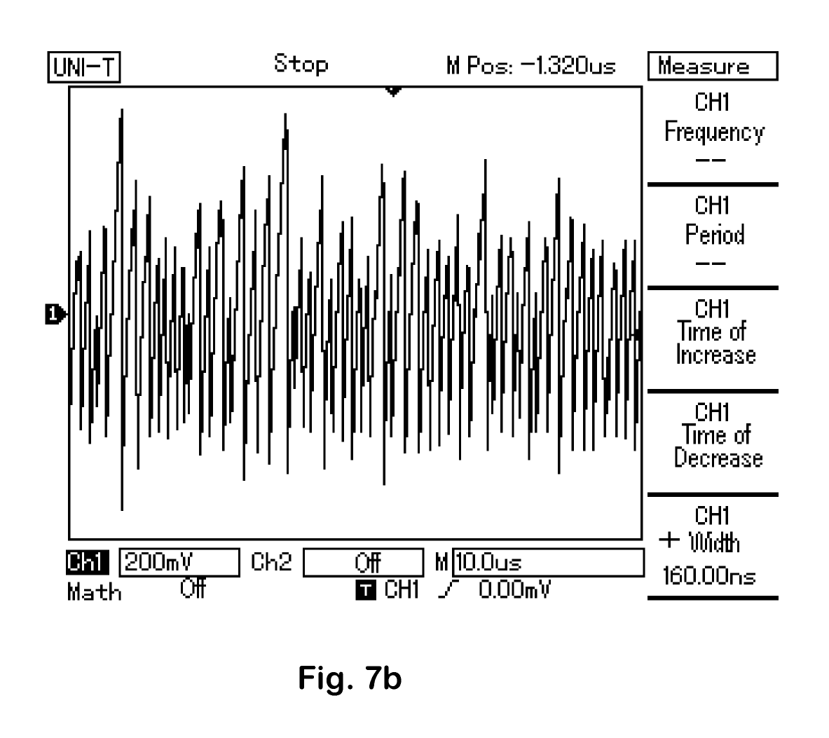

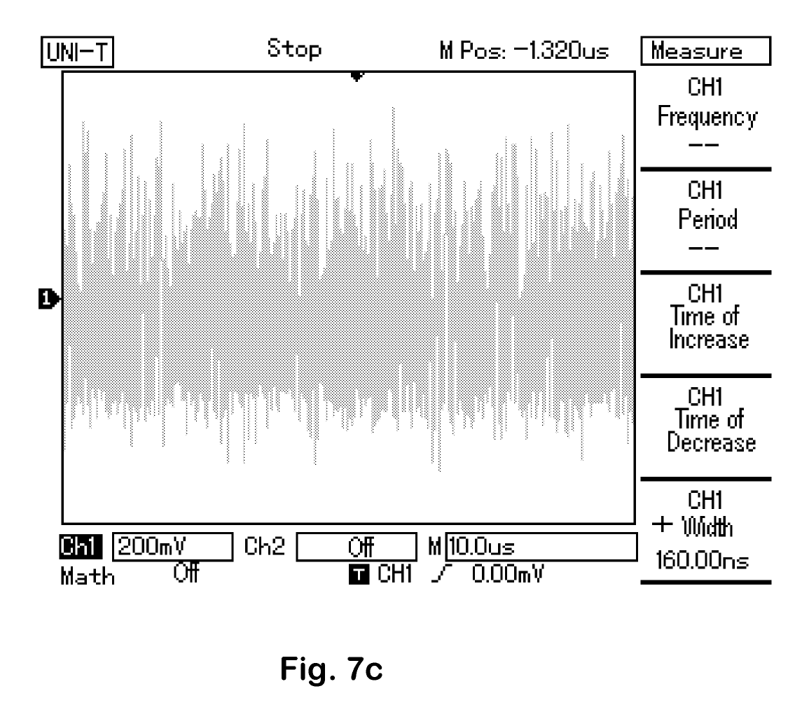

FIGS. 7a to 7c show the noise signals recorded with a circuit in accordance with FIG. 4a and at an operating point of 35 μA, which noise signals were recorded by an oscilloscope. In this case, the individual FIGS. 7a to 7c show different temporal resolutions of the noise signal.

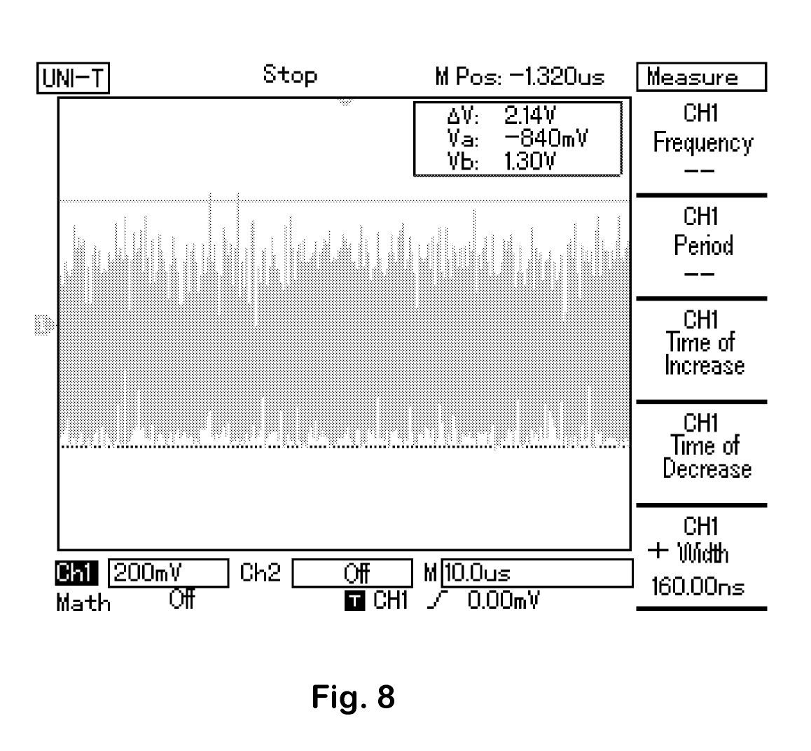

FIG. 8 shows the signal of a circuit comprising seven series-connected transistors, which signal was recorded by an oscilloscope. The series connection is effected by an analogous extension of the circuit illustrated in FIG. 4b, wherein the base of a first pnp transistor is connected to the emitter of a second pnp transistor, the base of the second pnp transistor is connected to the emitter of a third pnp transistor, etc. In this FIG. 8, a noise signal amplitude of approximately 2.14 V can be discerned, which indicates a pronounced avalanche effect.

With the device according to the invention it is possible to generate a noise signal which meets very stringent demands made of the signal-to-noise ratio. In particular, it is possible to realize noise sources which need no amplification for many further applications, which has advantages on account of small distortions. Moreover, the noise signal can be processed without amplification in the case of high-impedance coupling (for example in the case of more than 5 MΩ). Moreover, the device is distinguished by a low power consumption. This is owing to the fact firstly that the diode or diodes, in particular the transistor(s), is/are reverse-biased, for which reason only a small current flows through it/them. Thus, it is possible, for example, that given an applied voltage of 10 V the total current is only approximately 35 μA, such that the device can be operated with a comparatively small battery as voltage source. Moreover, on account of the primary noise signal amplitude that is high anyway, an amplifier can be dispensed with in many cases, which leads to a further reduction of the power consumption.

The generated noise signal also satisfies many recognized criteria and standards with regard to randomness that is expected of a noise system, such as, for example, the AIS31 standards, the NIST test and the diehard test.

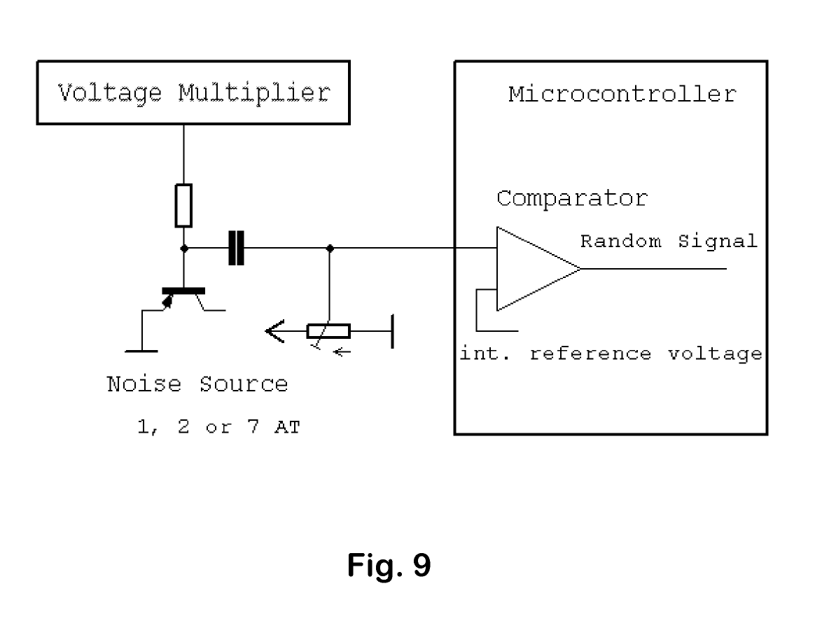

This is shown by the direct connection of different devices according to the invention for generating noise signals to a standard microcontroller in accordance with FIG. 9: in this case, a comparator as an integrated peripheral unit of a microcontroller is used to digitize an analogue noise signal. Previous solutions for such an application failed owing to the fact that no noise sources having a sufficient primary noise signal amplitude were available. The (standardized) examination was carried out with an avalanche transistor (AT), preferably with a series connection of two or seven avalanche transistors. A BCW70 was in each case used as transistor, and it was connected to a 12 V voltage source via a resistor of 100 kΩ. The capacitor (100 nF) serves for decoupling from the DC component. The operating point of the transistor was set with the aid of a potentiometer.

The noise signal generated by the apparatus in accordance with FIG. 9, said noise signal being illustrated in FIG. 4c, was subjected to an AIS31 test.

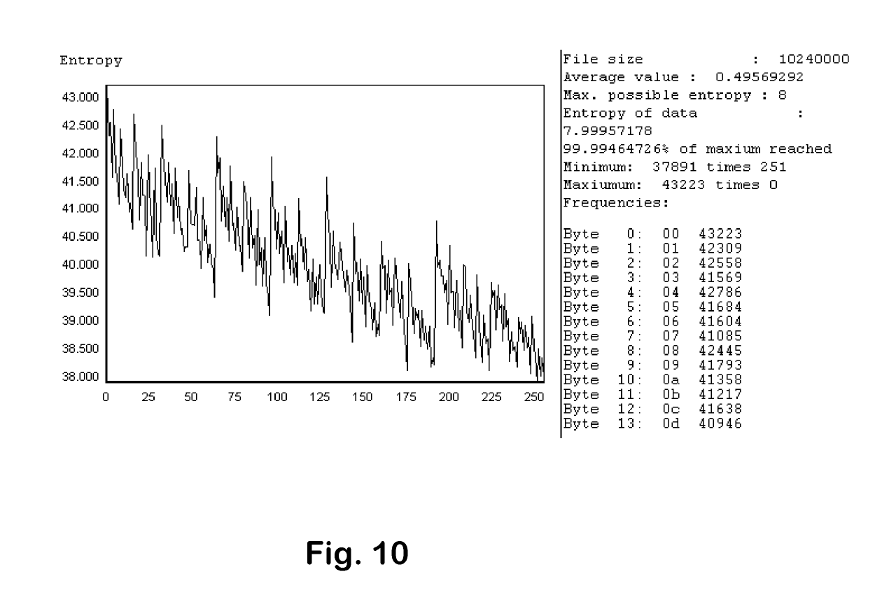

The digitized 8-bit noise signal generated by means of a single avalanche transistor had an entropy of 7.99957178, which is distinctly above the value of 7.97 (see the screenshot in FIG. 10). The noise signal therefore has a very good quality in this sense. The results of an NIST test and of a diehard test that were carried out with this processed noise signal also indicated a high-quality noise.

With two series-connected avalanche transistors this resulted in the noise signal shown in FIG. 4d. The entropy of the digitized primary noise signal was 7.99946884 in this case.

Finally, an entropy value of 7.99993702 resulted for seven series-connected transistors.

A further aspect of the invention relates to a method for generating a noise signal with the aid of a device as described above. In this case, said device is operated such that the diode(s) is/are reverse-biased. In the cases in which the diode is formed by a part of a transistor, the device is preferably operated such that the transistor is reverse-biased in the reverse direction of the emitter-base junction of the transistor. A noise having the advantageous properties described above can be generated in this way.

Preferably, in this method the operating point of the diode, in particular of the transistor, is in the range of 20 μA to 100 μA, preferably of 20 μA to 60 μA.

This operating point can furthermore preferably be set by an ohmic resistor. This possibility of setting the operating point is structurally particularly simple and additionally cost-effective.

Yet another aspect of the invention relates to the use of a device as described above for generating a noise signal and/or a random signal. Such random numbers can be generated in a manner known per se from the noise signal generated by the device according to the invention, for example with the aid of a Schmitt-trigger.

Moreover, the invention relates to a method for evaluating a type of an avalanche diode or of an avalanche transistor, comprising the following steps:

conducting a current through the avalanche diode or through the emitter-base junction of the avalanche transistor in the reverse direction;

deriving the voltage signal present between the poles of the avalanche diode or between the emitter and the base of the avalanche transistor;

digitizing the voltage signal in order to generate a digitized n-bit noise signal;

carrying out an AIS31 test with the digitized noise signal and determining the Shannon entropy of the digitized noise signal;

if the Shannon entropy is at least n/8×7.97: positive evaluation of the avalanche diode or the avalanche transistor; or, if the Shannon entropy is less than n/8×7.97: negative evaluation of the avalanche diode or the avalanche transistor.

This method therefore makes it possible to select, from a set of types of avalanche diodes or avalanche transistors, individual types of avalanche diode or avalanche transistors which are particularly suitable for generating random numbers. Specifically, the types of diodes or transistors are evaluated as positive and thus as suitable when the Shannon entropy achieved therewith has at least the threshold value of n/8×7.97. Against expectations, the inventors have totally surprisingly found that such high Shannon entropies could actually be obtained with avalanche diodes or avalanche transistors.

We claim:

1. Device for generating noise signals, comprising at least two series-connected diodes which are arranged in such a way that they are reverse-biased during intended operation of the device.

2. Device according to claim 1, wherein the diodes are avalanche diodes.

3. Device according to claim 1, wherein each diode is formed by a part of a transistor.

4. Device according to claim 3, wherein the transistors are avalanche transistors.

5. Device according to claim 3, wherein each diode is formed by the emitter-base junction of a transistor.

6. Device according to claim 5, wherein the Zener voltage of the emitter-base junction is in the range of 7.0 V to 12.0 V.

7. Device according to claim 3, wherein the base of a first transistor is connected to the emitter of a second transistor.

8. Device according to claim 1, containing at least two diodes which are connected in parallel with one another.

9. Device according claim 8, containing at least two transistors which are connected in parallel with one another.

10. Method for generating a noise signal with the aid of a device, wherein the device comprises at least two series-connected diodes which are arranged in such a way that they are reverse-biased during intended operation of the device and wherein the device is operated in such a way that the diodes are reverse-biased.

11. Method according to claim 10, wherein the diode is formed by the emitter-base junction of a transistor and the device is operated in such a way that the transistor is reverse-biased in the reverse direction of the emitter-base junction.

12. Method according to claim 10, wherein the operating point of the diode is in the range of 20 μA to 100 μA.

13. Method according to claim 11, wherein the operating point of the transistor is set by an ohmic resistor.

14. Method for evaluating a type of an avalanche diode or of an avalanche transistor, comprising the following steps:
a) conducting a current through the avalanche diode or through the emitter-base junction of the avalanche transistor in the reverse direction;
b) deriving the voltage signal present between the poles of the avalanche diode or between the emitter and the base of the avalanche transistor;
c) digitizing the voltage signal in order to generate a digitized n-bit noise signal;
d) carrying out an AIS31 test with the digitized noise signal and determining the Shannon entropy of the digitized noise signal;
e) if the Shannon entropy is at least n/8×7.97: positive evaluation of the avalanche diode or the avalanche transistor; or, if the Shannon entropy is less than n/8×7.97: negative evaluation of the avalanche diode or the avalanche transistor.
